(19) United States
(12) Patent Application Publication
(10) Pub. No.: US 2026/0221968 A1
(43) Pub. Date: Jul. 30, 2026

(54) SEMICONDUCTOR DEVICE AND SWITCHING CIRCUIT

(71) Applicants: ROHM CO., LTD., Kyoto (JP); Ancora Semiconductors Inc., Taoyuan City (TW)

(72) Inventors: Takumi FUJIMAKI, Kyoto (JP); Satoru NATE, Kyoto (JP); Ying-Chen LIU, Taoyuan City (TW); Wei-Hsiang CHAO, Taoyuan City (TW)

(21) Appl. No.: 19/456,797

(22) Filed: Jan. 22, 2026

(30) Foreign Application Priority Data
Jan. 29, 2025 (JP) 2025-012854

(51) Int. Cl. H03K 17/687; H02M 1/08; H03K 3/037

(52) U.S. Cl. CPC H03K 17/687; H02M 1/08; H03K 3/0377; H03K 2217/0063; H03K 2217/0072

(57) ABSTRACT

A semiconductor device includes: a resistor; a gallium nitride (GaN) power element; and a drive circuit configured to drive the GaN power element based on a pulse voltage, wherein the drive circuit includes a Schmitt trigger circuit, a high-side switch, and a low-side switch, wherein the pulse voltage is applied to a first end of the resistor, wherein a second end of the resistor is connected to an input terminal of the Schmitt trigger circuit and a first terminal of the high-side switch, wherein a second terminal of the high-side switch is connected to a first terminal of the low-side switch, and wherein each of the high-side switch and the low-side switch is switch-controlled based on an output of the Schmitt trigger circuit.

### CROSS-REFERENCE TO RELATED APPLICATION

This application is based upon and claims the benefit of priority from Japanese Patent Application No. 2025-012854, filed on January 29, 2025, the entire content of which is incorporated herein by reference.

### TECHNICAL FIELD

The present disclosure relates to a semiconductor device and a switching circuit.

### BACKGROUND

In recent years, semiconductor devices including gallium nitride (GaN) power elements are being increasingly commercialized.

### BRIEF DESCRIPTION OF DRAWINGS

The accompanying drawings, which are incorporated in and constitute a part of the specification, illustrate embodiments of the present disclosure.

FIG. 1 is a diagram showing a configuration of a semiconductor device according to a first embodiment.

FIG. 2 is a timing chart showing voltage and current waveforms at various portions of the semiconductor device according to the first embodiment.

FIG. 3 is a perspective view of an exterior of the semiconductor device according to the first embodiment.

FIG. 4 is a diagram showing a configuration of a semiconductor device according to a second embodiment.

FIG. 5 is a diagram showing a configuration of a semiconductor device according to a third embodiment.

FIG. 6 is a timing chart showing voltage waveforms at various portions of the semiconductor device according to the third embodiment.

FIG. 7 is a diagram showing a configuration of a semiconductor device according to a fourth embodiment.

FIG. 8 is a diagram showing a schematic configuration of a step-up DC/DC converter.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the present disclosure, a metal oxide semiconductor (MOS) field effect transistor refers to a field effect transistor having a gate structure constituted by at least three layers, which are a "layer made of a conductor or a semiconductor such as polysilicon with a low resistance," an "insulating layer," and a "P-type, N-type, or intrinsic semiconductor layer." In other words, a gate structure of the MOS field effect transistor is not limited to a three-layer structure of metal, oxide, and semiconductor.

In the present disclosure, a constant voltage refers to a voltage that is constant under ideal conditions, but in reality, it refers to a voltage that may slightly fluctuate due to a change in temperature or the like.

### First Embodiment

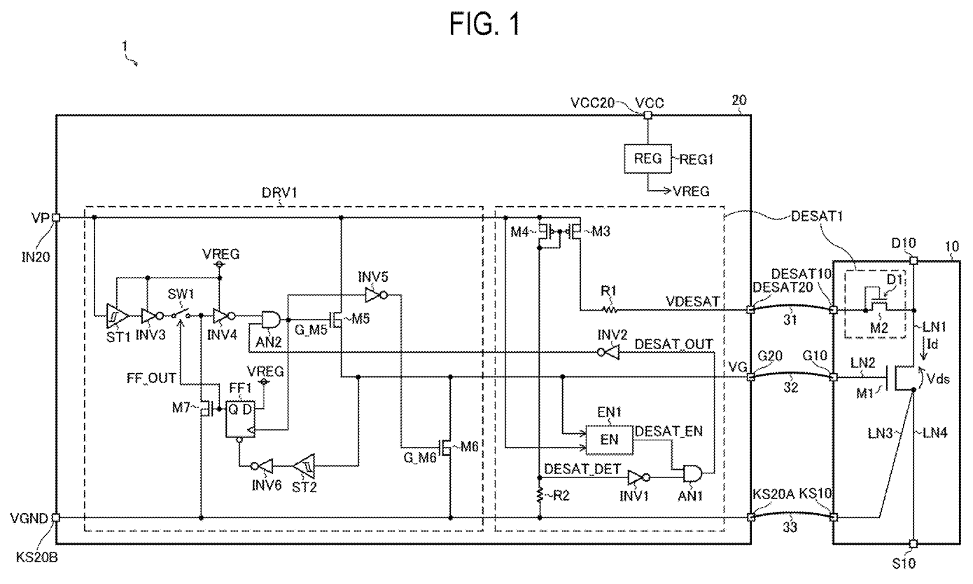

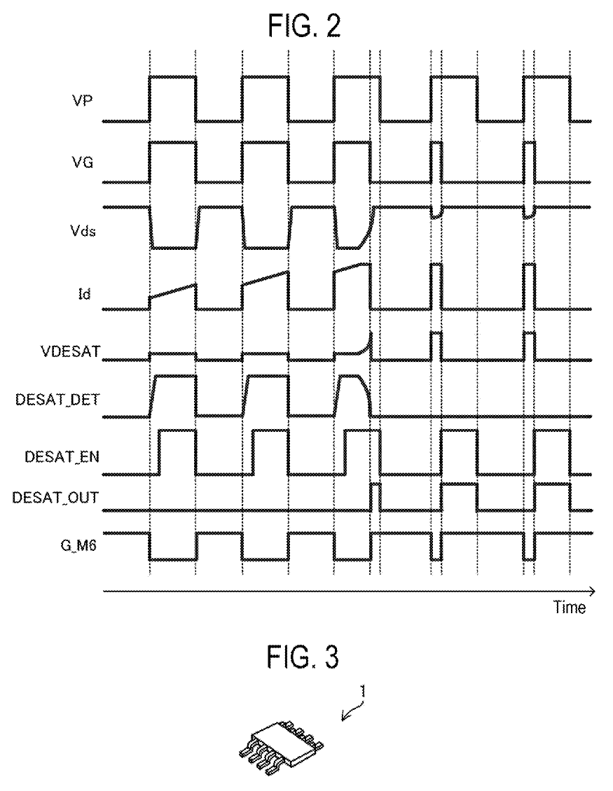

FIG. 1 is a diagram showing a configuration of a semiconductor device 1 according to a first embodiment. FIG. 2 is a timing chart showing voltage and current waveforms at various portions of the semiconductor device 1. FIG. 3 is a perspective view of an exterior of the semiconductor device 1. The semiconductor device 1 is an electronic component formed by encapsulating a GaN chip 10 and a Si chip 20, which will be described later, in a housing (package) made of resin. A plurality of external terminals are provided to be exposed from the housing of the semiconductor device 1, and include five external terminals that are electrically connected to pads D10, S10, IN20, KS20B, and VCC20 shown in FIG. 1, respectively. The number of external terminals of the semiconductor device 1 and the exterior of the semiconductor device 1 shown in FIG. 3 are merely examples.

The semiconductor device 1 shown in FIG. 1 includes the GaN chip 10 and the Si chip 20. The GaN chip 10 is, formed by, for example, dicing a silicon or sapphire substrate having a GaN thin film formed thereon into a chip shape. The GaN chip 10 may also be formed by, for example, dicing a GaN substrate into a chip shape. The Si chip 20 is formed by, for example, dicing a silicon substrate into a chip shape.

The GaN chip 10 includes a GaN power element M1, a diode D1, wirings LN1 to LN4, the pad D10, a pad DESAT10, a pad G10, a pad KS10, and the pad S10.

The GaN power element M1 is, for example, a high-electron mobility transistor made of GaN. A drain of the GaN power element M1 is electrically connected to the pad D10 via the wiring LN1 in the GaN chip 10. A gate of the GaN power element M1 is electrically connected to the pad G10 via the wiring LN2 in the GaN chip 10. A source of the GaN power element M1 is electrically connected to the pad KS10 via the wiring LN3, and is electrically connected to the pad S10 via the wiring LN4 in the GaN chip 10.

An anode of the diode D1 is electrically connected to the pad DESAT10. A cathode of the diode D1 is electrically connected to the drain of the GaN power element M1. By mounting the diode D1 on the GaN chip 10, a breakdown voltage of the diode D1 can be easily raised to the same level as that of the GaN power element M1.

The diode D1 is, for example, a high-electron mobility transistor M2, which is a diode-connected (a gate and a drain are short-circuited) GaN transistor. Since a current flowing through the high-electron mobility transistor M2 made of GaN is smaller than a current flowing through the GaN power element M1, a size of the high-electron mobility transistor M2 made of GaN can be made smaller than a size of the GaN power element M1. From a viewpoint of miniaturization and cost reduction of the GaN chip 10, the size of the high-electron mobility transistor M2 made of GaN may be smaller than the size of the GaN power element M1. In addition, unlike in the present embodiment, the diode D1 may be a PN junction diode.

The Si chip 20 includes a constant voltage source REG1, a driver DRV1, a portion of a monitoring circuit DESAT1 except for the diode D1, the pad IN20, the pad VCC20, a pad DESAT20, a pad G20, a pad KS20A, and the pad KS20B.

The pad DESAT20 provided in the Si chip 20 is electrically connected to the pad DESAT10 provided in the GaN chip 10 by a bonding wire 31. The pad G20 provided in the Si chip 20 is electrically connected to the pad G10 provided in the GaN chip 10 by a bonding wire 32. The pad KS20A provided in the Si chip 20 is electrically connected to the pad KS10 provided in the GaN chip 10 by a bonding wire 33.

The constant voltage source REG1 generates a constant voltage VREG from a voltage VCC applied to the pad VCC20 and supplies the constant voltage VREG to various portions in the Si chip 20.

Basically, when a pulse voltage VP applied to the pad IN20 is at a high level, the driver DRV1 turns on an N-channel MOS field effect transistor M5 in the driver DRV1 and turns off an N-channel MOS field effect transistor M6 in the driver DRV1, so that a drive voltage VG supplied to the pad G20 is set to a high level (see FIG. 2).

However, even when the pulse voltage VP applied to the pad IN20 is at a high level, when a voltage DESAT_OUT generated by the monitoring circuit DESAT1 is at a high level, the driver DRV1 turns off the N-channel MOS field effect transistor M5 in the driver DRV1 and turns on the N-channel MOS field effect transistor M6 in the driver DRV1, so that the drive voltage VG supplied to the pad G20 is set to a low level (see FIG. 2). In other words, when the voltage DESAT_OUT generated by the monitoring circuit DESAT1 is at the high level, the driver DRV1 turns off the GaN power element M1. With this configuration, the GaN power element M1 is protected when the GaN power element M1 is saturated, and thus it is possible to prevent the GaN power element M1 from being destroyed without overcurrent protection. The above-described protection performed by the semiconductor device 1 when the GaN power element M1 is saturated may be performed either with or without overcurrent protection for a drain current of the GaN power element M1.

Further, when the pulse voltage VP applied to the pad IN20 is at a low level, the driver DRV1 turns off the N-channel MOS field effect transistor M5 in the driver DRV1 and turns on the N-channel MOS field effect transistor M6 in the driver DRV1, so that the drive voltage VG supplied to the pad IN20 is set to a low level (see FIG. 2).

In the present embodiment, detailed description of the driver DRV1 is omitted.

The monitoring circuit DESAT1 includes the diode D1, a resistor R1, P-channel MOS field effect transistors M3 and M4, a resistor R2, an inverter (NOT gate) INV1, an enable circuit EN1, an AND gate AN1, and an inverter INV2.

The monitoring circuit DESAT1 monitors a drain-source voltage Vds of the GaN power element M1.

When the GaN power element M1 in an on state is not saturated, the drain-source voltage Vds becomes smaller than a voltage VDESAT supplied to the pad DESAT20, and the P-channel MOS field effect transistor M3 serving as a current source causes a current to flow through the diode D1 via the resistor R1 serving as a current-limiting resistor.

In contrast, when the GaN power element M1 in the on state is saturated, the drain-source voltage Vds becomes greater than the voltage VDESAT supplied to the pad DESAT20, and the P-channel MOS field effect transistor M3 serving as the current source does not cause a current to flow through the diode D1.

The P-channel MOS field effect transistor M4 serves as a mirror current source configured to generate a mirror current corresponding to a current output from the P-channel MOS field effect transistor M3, which serves as the current source.

The resistor R2 serves as a conversion element configured to convert the mirror current into a voltage DESAT_DET.

When the GaN power element M1 in the on state is not saturated, the voltage DESAT_DET becomes a high level. When the GaN power element M1 in the on state is saturated, the voltage DESAT_DET becomes a low level (the same level as a ground voltage VGND applied to the pad KS20B).

The enable circuit EN1 generates a voltage DESAT_EN as an enable signal. After a certain period of time (for example, 100 ns) has elapsed from a timing at which the voltage VG switches from the low level to the high level, the voltage DESAT_EN switches from a low level to a high level. At a timing at which the voltage VP switches from the high level to the low level, the voltage DESAT_EN switches from the high level to the low level. When the voltage DESAT_EN is at the high level, the protection function performed when the GaN power element M1 is saturated is enabled, and when the voltage DESAT_EN is at the low level, the protection function performed when the GaN power element M1 is saturated is disabled. By using the voltage DESAT_EN, it is possible to suppress the GaN power element M1 from being erroneously detected as being saturated.

The voltage DESAT_OUT is generated by a logical AND of an inverted signal of the voltage DESAT_DET and the voltage DESAT_EN. The inverted signal of the voltage DESAT_OUT is then supplied to the driver DRV1. When the inverted signal of the voltage DESAT_OUT is at a low level, a voltage G_M5 supplied to a gate of the N-channel MOS field effect transistor M5 in the driver DRV1 becomes a low level, a voltage G_M6 supplied to a gate of the N-channel MOS field effect transistor M6 in the driver DRV1 becomes a high level, and the drive voltage VG supplied to the pad G20 becomes a low level.

### Second Embodiment

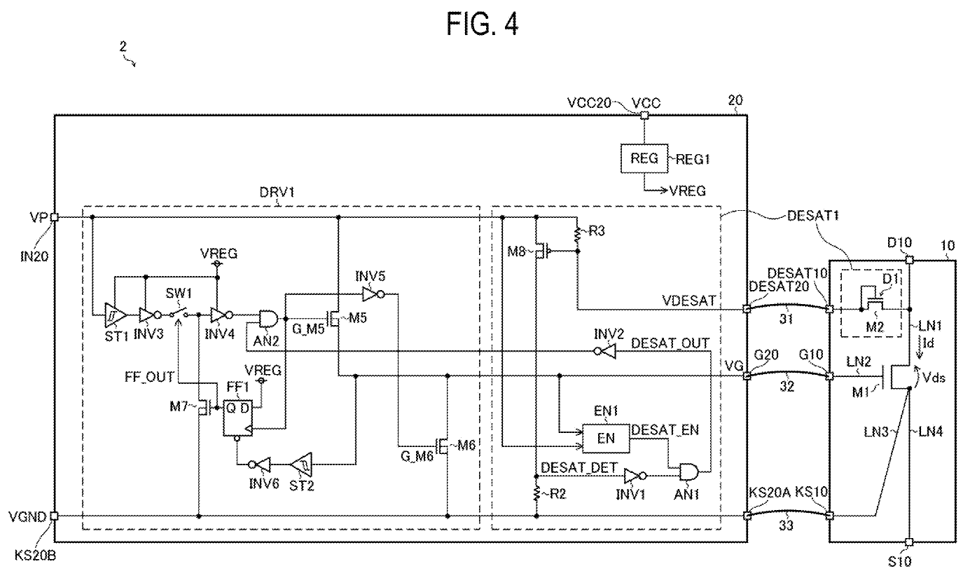

FIG. 4 is a diagram showing a configuration of a semiconductor device 2 according to a second embodiment. The semiconductor device 2 is basically the same as the semiconductor device 1 except for a configuration of a monitoring circuit DESAT1.

The monitoring circuit DESAT1 according to the present embodiment includes a resistor R3 and a P-channel MOS field effect transistor M8, instead of the P-channel MOS field effect transistors M3 and M4 and the resistor R1.

When the GaN power element M1 in the on state is not saturated, the drain-source voltage Vds becomes smaller than the voltage VDESAT supplied to the pad DESAT20, and the resistor R3 serving as a current source causes a current to flow through the diode D1. At this time, an electrical potential difference across the resistor R3 exceeds a threshold voltage of the P-channel MOS field effect transistor M8, causing the P-channel MOS field effect transistor M8 to be turned on. When the P-channel MOS field effect transistor M8 is turned on, a current flows through the resistor R2, and an electrical potential difference is generated across the resistor R2. Thus, the voltage DESAT_DET becomes a high level.

In contrast, when the GaN power element M1 in the on state is saturated, the drain-source voltage Vds becomes greater than the voltage VDESAT supplied to the pad DESAT20, and the resistor R3 serving as the current source does not cause a current to flow through the diode D1. In this case, since no electrical potential difference is generated across the resistor R3, a gate-source voltage of the P-channel MOS field effect transistor M8 becomes zero, causing the P-channel MOS field effect transistor M8 to be turned off. When the P-channel MOS field effect transistor M8 is turned off, no current flows through the resistor R2, and no electrical potential difference is generated across the resistor R2. Thus, the voltage DESAT_DET becomes a low level (the same level as the ground voltage VGND applied to the pad KS20B).

### Third Embodiment

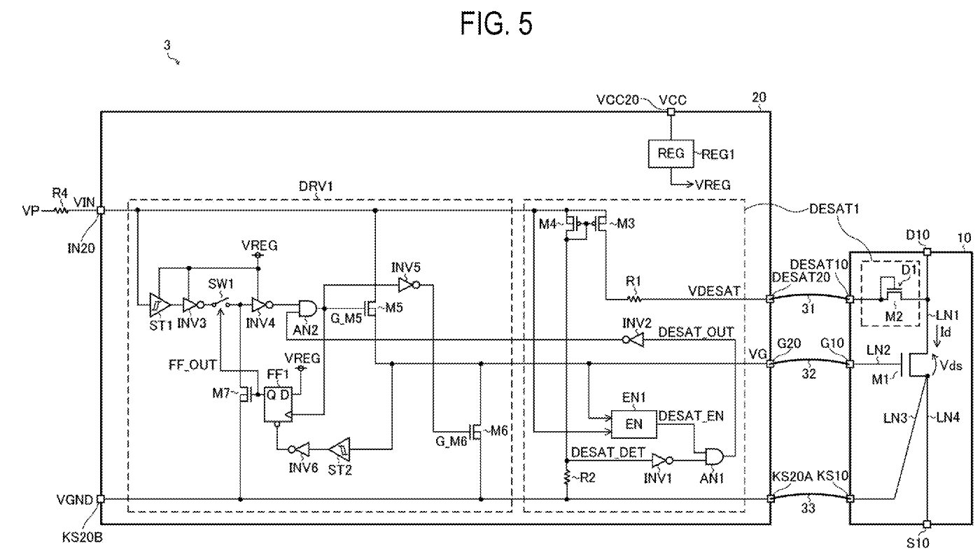

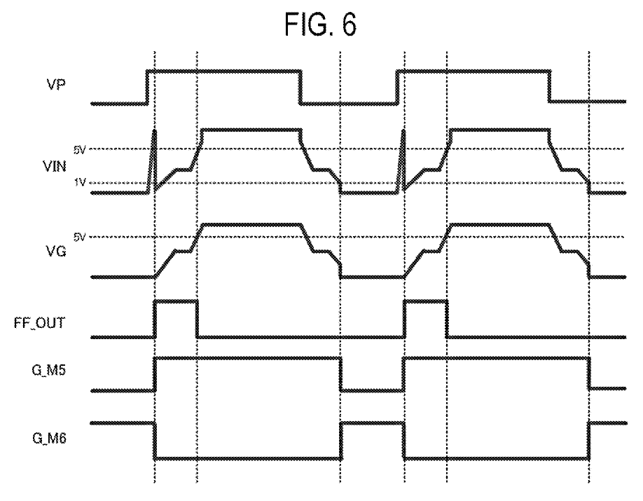

FIG. 5 is a diagram showing a configuration of a semiconductor device 3 according to a third embodiment. FIG. 6 is a timing chart showing voltage waveforms at various portions of the semiconductor device 3 according to the third embodiment. The semiconductor device 3 is basically the same as the semiconductor device 1 except that the semiconductor device 3 further includes a resistor R4.

The resistor R4 is disposed outside the Si chip 20 and the GaN chip 10.

The driver DRV1 includes a Schmitt trigger circuit ST1, inverters INV3 and INV4, an AND gate AN2, an N-channel MOS field effect transistor M5 serving as a high-side switch, an inverter INV5, and an N-channel MOS field effect transistor M6 serving as a low-side switch.

The driver DRV1 further includes a Schmitt trigger circuit ST2, an inverter INV6, a flip-flop FF1, a switch SW1, and an N-channel MOS field effect transistor M7.

In the following description, it is assumed that the GaN power element M1 is not saturated.

A current capability of the driver DRV1 when the N-channel MOS field effect transistor M5 is turned on is determined by a resistance value of the resistor R4. As the resistance value of the resistor R4 becomes larger, a current flowing through the N-channel MOS field effect transistor M5 becomes smaller, resulting in a smaller slew rate of the voltage VG and reduction in EMI noise. In other words, a magnitude of EMI noise when the N-channel MOS field effect transistor M5 is turned on can be regulated by the resistor R4.

The N-channel MOS field effect transistor M6 has a current capacity that can prevent self-turn-on of the GaN power element M1.

A voltage VIN, which is applied to the pad IN20, is supplied to an input terminal of the Schmitt trigger circuit ST1. The voltage VIN is a voltage that corresponds to the pulse voltage VP.

The voltage VIN is applied to a drain of the N-channel MOS field effect transistor M5, and the N-channel MOS field effect transistors M5 and M6 are switch-controlled based on an output of the Schmitt trigger circuit ST1. As a result, in a state where the N-channel MOS field effect transistor M5 is turned on and the N-channel MOS field effect transistor M6 is turned off, the voltage VG becomes a low level, causing the GaN power element M1 to be turned off.

In addition, when the voltage VIN is lower than a first logic threshold (e.g., 1 V) of the Schmitt trigger circuit ST1, the N-channel MOS field effect transistor M6 is turned on (see FIG. 6). In the present embodiment, the first logic threshold of the Schmitt trigger circuit ST1 is set to be lower than a plateau voltage of the GaN power element M1. Thus, in the present embodiment, the N-channel MOS field effect transistor M6 is turned on after the GaN power element M1 is completely turned off. Therefore, the N-channel MOS field effect transistor M6 has a current capacity that can prevent self-turn-on of the GaN power element M1, that is, a high current capacity, and can suppress an increase in EMI noise.

As described above, the semiconductor device 3 can regulate the EMI noise and can suppress the self-turn-on of the GaN power element M1.

In a case in which the resistance value of the resistor R4 is large, when the N-channel MOS field effect transistor M5 switches from an off state to an on state, the voltage VP is divided by the resistor R4 and an on resistance of the N-channel MOS field effect transistor M5. Thus, an amount of voltage drop in the voltage VIN increases, causing the voltage VIN to fall below the first logic threshold of the Schmitt trigger circuit ST1, and the switch-control of the N-channel MOS field effect transistors M5 and M6 may malfunction.

As a countermeasure against the above malfunction, the driver DRV1 includes the flip-flop FF1 and the switch SW1. From when the voltage VIN exceeds a second logic threshold (e.g., 5 V) of the Schmitt trigger circuit ST1 until the voltage VG exceeds the second logic threshold, the N-channel MOS field effect transistor M5 is kept turned on and the N-channel MOS field effect transistor M6 is kept turned off (see FIG. 6). In order to implement the above operation, a first logic threshold of the Schmitt trigger circuit ST2, which is provided to reset the flip-flop FF1, is set to the same value as the first logic threshold of the Schmitt trigger circuit ST1, and a second logic threshold of the Schmitt trigger circuit ST2 is set to the same value as the second logic threshold of the Schmitt trigger circuit ST1.

### Fourth Embodiment

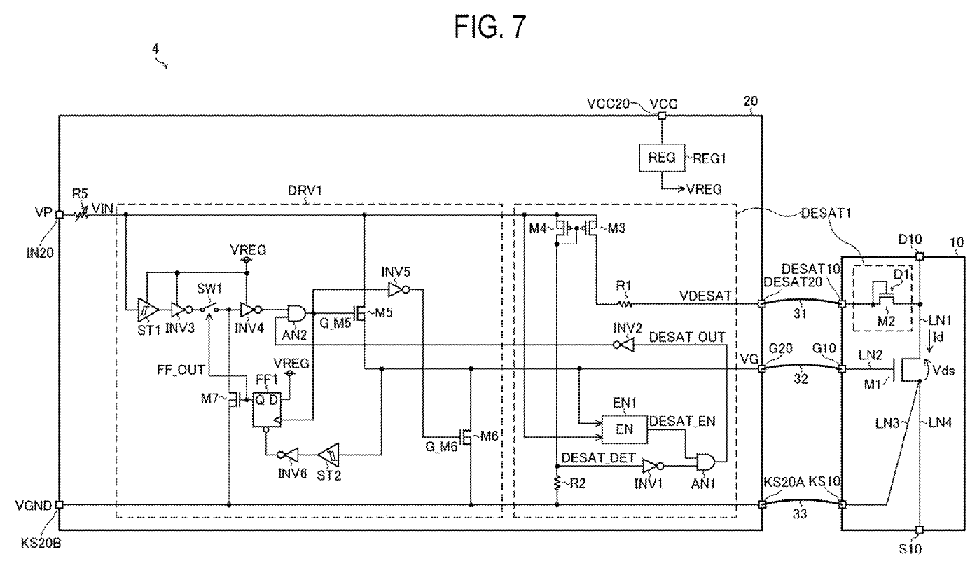

FIG. 7 is a diagram showing a configuration of a semiconductor device 4 according to a fourth embodiment. The semiconductor device 4 is basically the same as the semiconductor device 1 except that the semiconductor device 4 includes a variable resistor R5, which is provided instead of the resistor R4 and mounted on the Si chip 20.

The variable resistor R5 is constituted by, for example, a circuit including a plurality of resistors and a plurality of switches, and a resistance value of the variable resistor R5 can be adjusted by switching an on/off state of each of the plurality of switches.

### Application to Switching Circuit

Each of the above-described semiconductor devices 1 to 4 can be used, for example, as a portion of a switching circuit. Examples of the switching circuit may include a switching power supply circuit, a motor driver circuit, and the like.

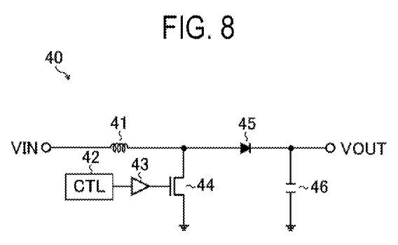

FIG. 8 is a diagram showing a schematic configuration of a step-up DC/DC converter as an example of a switching power supply circuit. A step-up DC/DC converter 40 shown in FIG. 8 includes an inductor 41, a controller 42, a driver 43, a switching element 44, a diode 45, and a capacitor 46.

When the controller 42 turns on the switching element 44 via the driver 43, a current flows from an application terminal of an input voltage VIN to the switching element 44 via the inductor 41, thereby storing energy in the inductor 41. When the controller 42 switches the switching element 44 from the on state to an off state via the driver 43, the energy stored in the inductor 41 is released, and a current flows from the inductor 41 to the capacitor 46 via the diode 45, thereby charging the capacitor 46 with an output voltage VOUT which is higher than the input voltage VIN.

Each of the above-described semiconductor devices 1 to 4 can be used as the driver 43 and the switching element 44 in the step-up DC/DC converter 40 shown in FIG. 8.

### Others

The above-described embodiments should be considered illustrative and not restrictive in all respects. The technical scope of the present disclosure is defined by the claims, not the description of the above-described embodiments, and should be understood to include all modifications that fall within the meaning and scope of equivalents of the claims.

For example, the third and fourth embodiments may be modified to a configuration that does not include the monitoring circuit DESAT1. In this case, the AND gate AN2 may be removed from the driver DRV1, and an output terminal of the inverter INV4 may be connected to a gate of the P-channel MOS field effect transistor M5, an input terminal of the inverter INV5, and a clock input terminal of the flip-flop FF1.

### Supplementary Notes

The following supplementary notes are provided for the present disclosure, the specific configuration examples of which are shown in the above-described embodiments.

A semiconductor device (3, 4) of the present disclosure includes: a resistor (R4, R5), a GaN power element (M1), and a drive circuit (DRV1) configured to drive the GaN power element based on a pulse voltage, wherein the drive circuit includes a Schmitt trigger circuit (ST1), a high-side switch (M5), a low-side switch (M6), wherein the pulse voltage is applied to a first end of the resistor, wherein a second end of the resistor is connected to an input terminal of the Schmitt trigger circuit and a first terminal of the high-side switch, wherein a second terminal of the high-side switch is connected to a first terminal of the low-side switch, and wherein each of the high-side switch and the low-side switch is switch-controlled based on an output of the Schmitt trigger circuit (first configuration).

With the semiconductor device of the first configuration, it is possible to regulate EMI noise and to suppress self-turn-on of the GaN power element.

The semiconductor device of the first configuration may further include a Si chip (20) and a GaN chip (10), wherein the resistor is disposed outside the Si chip and the GaN chip, wherein the drive circuit is mounted on the Si chip, and wherein the GaN power element is mounted on the GaN chip (second configuration).

In the semiconductor device of the first or second configuration, the drive circuit may be further configured to turn on the low-side switch when a voltage applied to the input terminal of the Schmitt trigger circuit is lower than a first logic threshold of the Schmitt trigger circuit (third configuration).

In the semiconductor device of the third configuration, the first logic threshold may be lower than a plateau voltage of the GaN power element (fourth configuration).

In the semiconductor device of any one of the first to fourth configurations, the drive circuit may be further configured such that, from when a voltage applied to the input terminal of the Schmitt trigger circuit exceeds a second logic threshold of the Schmitt trigger circuit until a voltage applied to the second terminal of the high-side switch and the first terminal of the low- side switch exceeds the second logic threshold, the high-side switch is kept turned on and the low-side switch is kept turned off, and the second logic threshold may be greater than a first logic threshold of the Schmitt trigger circuit (fifth configuration).

A switching circuit (40) of the present disclosure may include the semiconductor device of any one of the first to fifth configurations (sixth configuration).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a resistor;
a gallium nitride (GaN) power element; and
a drive circuit configured to drive the GaN power element based on a pulse voltage,
wherein the drive circuit includes a Schmitt trigger circuit, a high-side switch, and a low-side switch,
wherein the pulse voltage is applied to a first end of the resistor,
wherein a second end of the resistor is connected to an input terminal of the Schmitt trigger circuit and a first terminal of the high-side switch,
wherein a second terminal of the high-side switch is connected to a first terminal of the low-side switch, and
wherein each of the high-side switch and the low-side switch is switch-controlled based on an output of the Schmitt trigger circuit.

2. The semiconductor device of claim 1, further comprising:
a silicon (Si) chip; and
a GaN chip,
wherein the resistor is disposed outside the Si chip and the GaN chip,
wherein the drive circuit is mounted on the Si chip, and
wherein the GaN power element is mounted on the GaN chip.

3. The semiconductor device of claim 1, wherein the drive circuit is further configured to turn on the low-side switch when a voltage applied to the input terminal of the Schmitt trigger circuit is lower than a first logic threshold of the Schmitt trigger circuit.

4. The semiconductor device of claim 3, wherein the first logic threshold is lower than a plateau voltage of the GaN power element.

5. The semiconductor device of claim 1,
wherein the drive circuit is further configured such that, from when a voltage applied to the input terminal of the Schmitt trigger circuit exceeds a second logic threshold of the Schmitt trigger circuit until a voltage applied to the second terminal of the high-side switch and the first terminal of the low-side switch exceeds the second logic threshold, the high-side switch is kept turned on and the low-side switch is kept turned off, and
wherein the second logic threshold is greater than a first logic threshold of the Schmitt trigger circuit.

6. A switching circuit comprising the semiconductor device of claim 1.
